(19) United States
(12) Patent Application Publication
(10) Pub. No.: US 2025/0151279 A1
(43) Pub. Date: May 8, 2025

(54) SEMICONDUCTOR DEVICE AND ELECTRONIC SYSTEM INCLUDING THE SAME

(71) Applicant: SAMSUNG ELECTRONICS CO., LTD., SUWON-SI (KR)

(72) Inventors: JUNHYOUNG KIM, Suwon-si (KR); JIYOUNG KIM, Suwon-si (KR); IK-HYUNG JOO, Suwon-si (KR); SUKKANG SUNG, Suwon-si (KR); SEHOON LEE, Suwon-si (KR)

(21) Appl. No.: 18/668,971

(22) Filed: May 20, 2024

(30) Foreign Application Priority Data
Nov. 3, 2023 (KR) 10-2023-0151201

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

A semiconductor device includes a semiconductor substrate, and a first transistor disposed on the semiconductor substrate. The first transistor includes an insulation structure disposed on the semiconductor substrate, a channel region disposed on the insulation structure and including a first semiconductor layer, and extending in a direction crossing the semiconductor substrate, first source and drain regions electrically connected to the channel region, a first gate insulating layer disposed on the channel region, and a first gate electrode disposed on the first gate insulating layer. A first region that is one of the first source and drain regions and a second region that is another one of the first source and drain regions include different materials or have different crystal structures.

### CROSS-REFERENCE TO RELATED APPLICATION

This application claims priority under 35 U.S.C. § 119 to Korean Patent Application No. 10-2023-0151201, filed in the Korean Intellectual Property Office on Nov. 3, 2023, the entire contents of which is incorporated by reference herein in its entirety.

### TECHNICAL FIELD

Embodiments of the present disclosure relate to a semiconductor device and an electronic system including the same.

### DISCUSSION OF RELATED ART

A small yet multifunctional semiconductor device may be used in various electronic industries. As advancements are made in the electronic industry, research on improving performance and an integration degree of a semiconductor device has continued. For example, the integration degree of the semiconductor device may be improved by reducing a distance between a plurality of circuit elements included in the semiconductor device.

### SUMMARY

Embodiments of the present disclosure provide a semiconductor device capable of enhancing performance and an integration degree and an electronic system including the same.

A semiconductor device according to an embodiment includes a semiconductor substrate, and a first transistor disposed on the semiconductor substrate. The first transistor includes an insulation structure disposed on the semiconductor substrate, a channel region disposed on the insulation structure and including a first semiconductor layer, and extending in a direction crossing the semiconductor substrate, first source and drain regions electrically connected to the channel region, a first gate insulating layer disposed on the channel region, and a first gate electrode disposed on the first gate insulating layer. A first region that is one of the source and drain regions and a second region that another one of the first source and drain regions include different materials or have different crystal structures.

A semiconductor device according to an embodiment includes a semiconductor substrate, and a plurality of transistors disposed on the semiconductor substrate and including a first transistor and a second transistor having different structures. The first transistor includes an insulation structure disposed on the semiconductor substrate, a channel region disposed on the insulation structure and including a first semiconductor layer, and extending in a direction inclined or vertical to the semiconductor substrate, source and drain regions electrically connected to the channel region, a gate insulating layer disposed on the channel region, and a gate electrode disposed on the gate insulating layer. One of the source and drain regions includes a partial portion of the semiconductor substrate.

An electronic system according to an embodiment includes a main substrate, the semiconductor device disposed on the main substrate, and a controller electrically connected to the semiconductor device on the main substrate.

According to an embodiment, a high voltage transistor has a vertical structure (e.g., a vertical channel structure), which may enhance an integration degree. Further, a second region that is one of the source and drain regions of the high voltage transistor includes a partial portion of the semiconductor substrate, which may enhance performance of the high voltage transistor.

### BRIEF DESCRIPTION OF THE DRAWINGS

FIG. 1 is a partial cross-sectional view schematically illustrating a semiconductor device according to an embodiment.

FIG. 2 is an enlarged cross-sectional view illustrating an example of a channel structure included in the semiconductor device illustrated in FIG. 1.

FIG. 3 is a partial plan view schematically illustrating a circuit region included in the semiconductor device illustrated in FIG. 1.

FIG. 4 is a cross-sectional view schematically illustrating a partial portion of a circuit region included in the semiconductor device illustrated in FIG. 1.

FIG. 5 is a plan view schematically illustrating a first transistor and a second transistor included in the circuit region illustrated in FIG. 3.

FIGS. 6, 7, 8, 9, 10, 11 and 12 are cross-sectional views illustrating a manufacturing method of a semiconductor device according to an embodiment.

FIG. 13 is an enlarged plan view illustrating a partial portion of a semiconductor device according to an embodiment.

FIG. 14 is an enlarged plan view illustrating a partial portion of a semiconductor device according to an embodiment.

FIG. 15 is a cross-sectional view schematically illustrating a semiconductor device according to an embodiment.

FIG. 16 is a view schematically illustrating an electronic system including a semiconductor device according to an embodiment.

FIG. 17 is a perspective view schematically illustrating an electronic system including a semiconductor device according to an embodiment.

FIG. 18 is a cross-sectional view schematically illustrating a semiconductor package according to an embodiment.

FIG. 19 is a cross-sectional view schematically illustrating a semiconductor package according to an embodiment.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not necessarily limited to the embodiment provided herein.

A portion unrelated to the description is omitted to clearly describe the present disclosure, and the same or similar components are denoted by the same reference numeral throughout the present specification.

It will be understood that when a component such as a layer, film, region, or substrate is referred to as being “on” another component, it may be directly on other component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, unless explicitly described to the contrary, the word “comprise”, and variations such as “comprises” or “comprising”, will be understood to imply the inclusion of stated elements but not the exclusion of any other elements.

Further, throughout the specification, a phrase “on a plane”, “in a plane”, “on a plan view”, or “in a plan view” may indicate a case where a portion is viewed from above or a top portion, and a phrase “on a cross-section” or “in a cross-section” may indicate when a cross-section taken along a vertical direction is viewed from a side.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

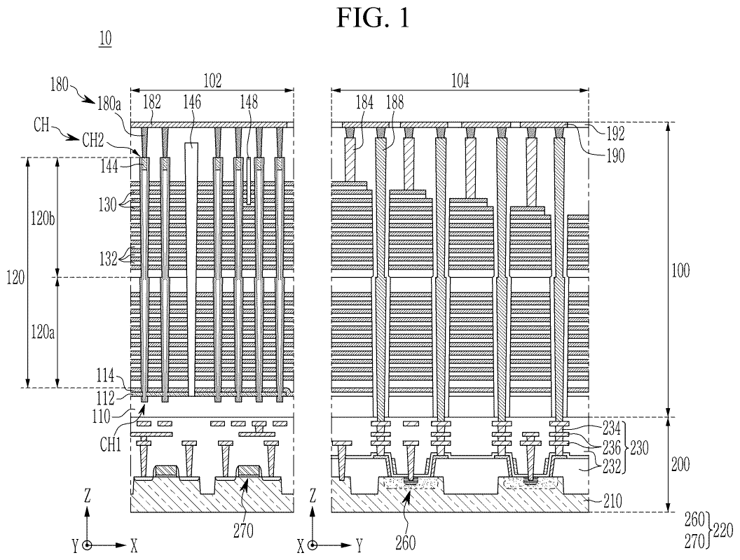

Hereinafter, with reference to FIG. 1 to FIG. 12, a semiconductor device and a manufacturing method of the same according to an embodiment will be described in detail.

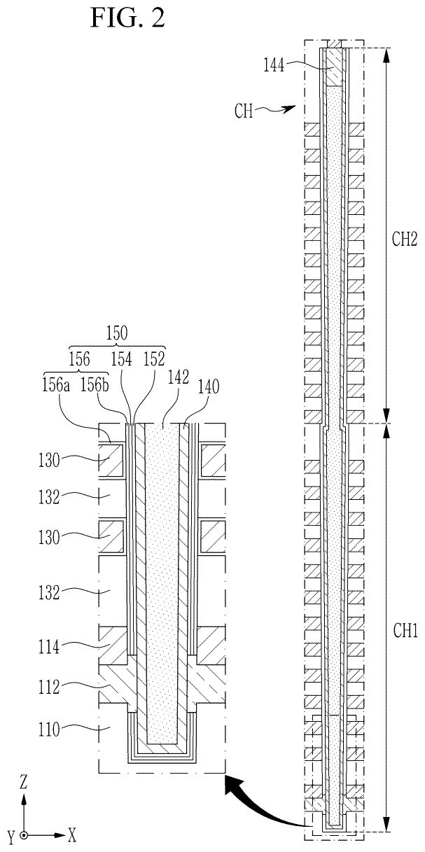

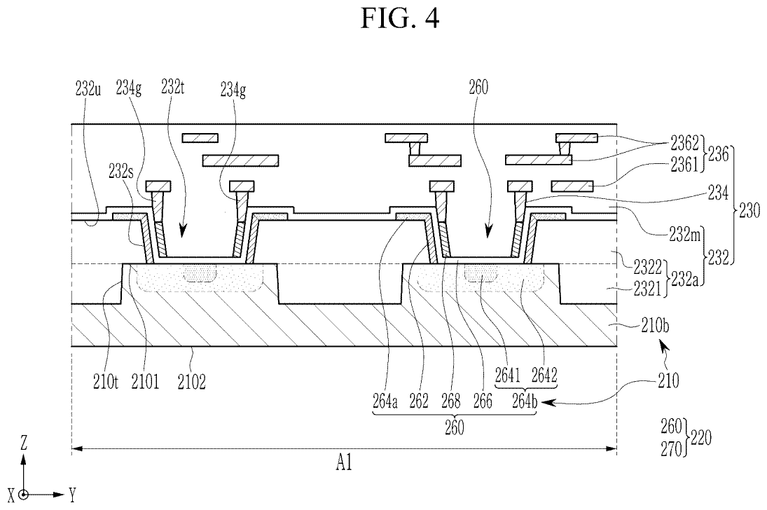

FIG. 1 is a partial cross-sectional view schematically illustrating a semiconductor device 10 according to an embodiment. FIG. 2 is an enlarged cross-sectional view illustrating an example of a channel structure CH included in the semiconductor device 10 illustrated in FIG. 1. For a clear understanding, coordinates of FIG. 1 are mainly based on a cell region 100, and a cross-sectional view of a circuit region 200 taken along a line A-A′ of FIG. 4 is illustrated in FIG. 1 regardless of the coordinates.

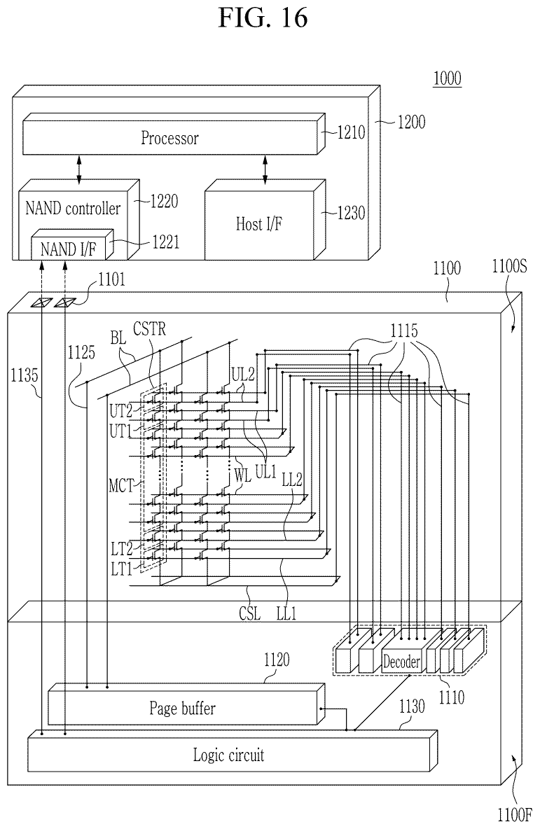

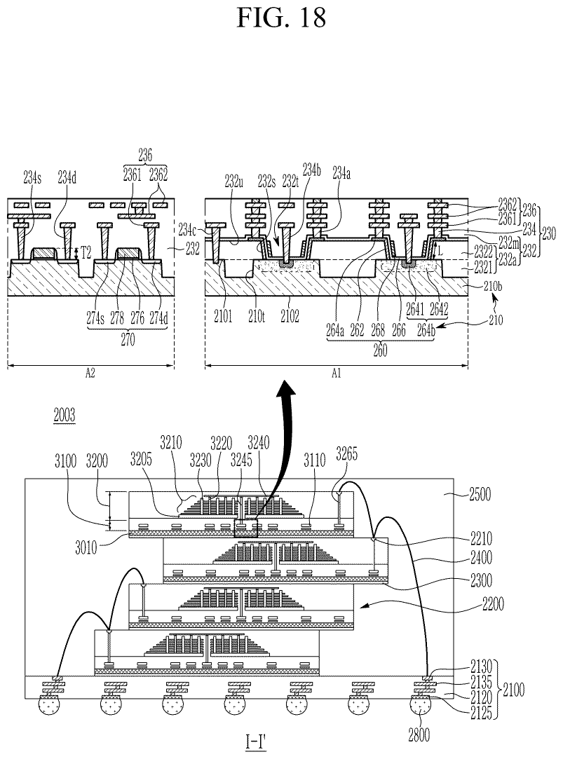

Referring to FIG. 1 and FIG. 2, a semiconductor device 10 according to an embodiment may include a cell region 100 including a memory cell structure and a circuit region 200 including a peripheral circuit structure controlling an operation of the memory cell structure. For example, the circuit region 200 and the cell region 100 may correspond to a first structure 1100F and a second structure 1100S of a semiconductor device 1100 included in an electronic system 1000 illustrated in FIG. 16, respectively. In some embodiments, the circuit region 200 and the cell region 100 may include a first structure 3100 and a second structure 3200 of a semiconductor chip 2200 illustrated in FIG. 18, respectively.

Here, the circuit region 200 may include the peripheral circuit structure on a first substrate 210, and the cell region 100 may include a gate stacking structure 120 and a channel structure CH on a second substrate 110 as the memory cell structure. The circuit region 200 may include a first wiring portion 230, and the cell region 100 may include a second wiring portion 180 electrically connected to the memory cell structure.

In an embodiment, the cell region 100 may be disposed on the circuit region 200. Accordingly, an area corresponding to the circuit region 200 does not need to be secured separately from the cell region 100. Therefore, an area of the semiconductor device 10 may be reduced. However, the embodiments are not necessarily limited thereto, and modifications may be made. For example, the circuit region 200 may be disposed next to the cell region 100.

The cell region 100 may include a cell array region 102 and a connection region 104. The gate stacking structure 120 and the channel structure CH may be disposed on the second substrate 110 in the cell array region 102. A structure that connects the gate stacking structure 120 and/or the channel structure CH in the cell array region 102 to the circuit region 200 or an external circuit may be in the cell array region 102 and/or the connection region 104.

In an embodiment, the second substrate 110 may include a semiconductor layer including a semiconductor material. For example, the second substrate 110 may be a semiconductor substrate including or formed of a semiconductor material or may be a semiconductor substrate in which a semiconductor layer is disposed on a base substrate. For example, the second substrate 110 may include or formed of silicon, germanium, silicon-germanium, silicon on insulator, germanium on insulator, or the like. Here, the semiconductor layer included in the second substrate 110 may be doped with a p-type dopant or an n-type dopant. For example, the p-type dopant may include boron (B), gallium (Ga), or the like, and the n-type dopant may include phosphorus (P), arsenic (As), or the like. However, the embodiments are not necessarily limited to a material of the second substrate 110, a conductive type of the dopant doped to the semiconductor layer, or the like.

In the cell array region 102, the gate stacking structure 120 and the channel structure CH may be positioned. The gate stacking structure 120 may include cell insulation layers 132 and gate lines 130 alternately stacked on a first surface (e.g., a front surface or an upper surface) of the second substrate 110. The channel structure CH may extend in a direction crossing the second substrate 110 (a Z-axis direction in the drawings) while penetrating the gate stacking structure 120. For example, the channel structure CH may be disposed perpendicular to the cell insulation layer 132 and the gate lines 130.

In an embodiment, first and/or second horizontal conductive layers 112 and 114 may be provided between the second substrate 110 and the gate stacking structure 120 in the cell array region 102. For example, the horizontal conductive layers 112 and 114 may be disposed sequentially on the second substrate 110 and below the gate stacking structure 120. The first and second horizontal conductive layers 112 and 114 may electrically connect (e.g., directly connect) the channel structure CH and the second substrate 110. The first horizontal conductive layer 112 may act as a partial portion of a common source line of the semiconductor device 10. For example, the first horizontal conductive layer 112 may act as the common source line together with the second substrate 110.

The first and the second horizontal conductive layers 112 and 114 may include a semiconductor material (e.g., polycrystalline silicon). For example, the first horizontal conductive layer 112 may include a polycrystalline silicon layer including a dopant. The embodiments are not necessarily limited thereto. The second horizontal conductive layer 114 may include a material (e.g., an insulating material) different from a material of the first horizontal conductive layer 112, or the second horizontal conductive layer 114 might not be provided.

The gate stacking structure 120 in which the cell insulation layers 132 and the gate lines 130 are alternately stacked may be disposed on the second substrate 110 (e.g., on the first and second horizontal conductive layers 112 and 114 disposed on the second substrate 110).

The gate line 130 may include any of various conductive materials. For example, the gate line 130 may include a metal material such as tungsten (W), copper (Cu), aluminum (Al), or the like, polycrystalline silicon, metal nitride (e.g., titanium nitride (TiN), tantalum nitride (TaN), or the like), or a combination thereof. As illustrated in an enlarged view of FIG. 2, a partial portion of a blocking layer 156 (e.g., a first blocking layer 156a) including an insulating material may be disposed at an outside of the gate line 130. The cell insulation layer 132 may include any of various insulating materials such as, for example, silicon oxide, silicon nitride, silicon oxynitride, a low dielectric constant material having a lower dielectric constant than silicon oxide, or a combination thereof.

In an embodiment, the channel structure CH may be provided. The channel structure CH may penetrate the gate stacking structure 120 and extend in a direction crossing the second substrate 110 (e.g., a direction perpendicular to the second substrate 110 or the Z-axis).

The channel structure CH may include a channel layer 140, and a gate dielectric layer 150 disposed on the channel layer 140 between the gate line 130 and the channel layer 140. The channel structure CH may further include a core insulation layer 142 at an inside of the channel layer 140. In some embodiments, the core insulation layer 142 might not be provided. The channel structure CH may further include a channel pad 144 disposed on the channel layer 140 and/or the gate dielectric layer 150. The gate dielectric layer 150 disposed between the gate line 130 and the channel layer 140 may include a tunneling layer 152, a charge storage layer 154, and a blocking layer 156 sequentially disposed on the channel layer 140. For example, the tunneling layer 152 may be disposed closer to the channel layer 140 than the charge storage layer 154 and the blocking layer 156.

Each channel structure CH forms one memory cell string, and a plurality of channel structures CH may be spaced apart from each other while forming rows and columns when viewed in a plan view. For example, a plurality of channel structures CH may be disposed to form any of various shapes such as a lattice shape, a zigzag shape, or the like in a plan view. The channel structure CH may have a pillar shape. For example, in a cross-sectional view, the channel structure CH may have an inclined side surface so that a width of the channel structure CH decreases as the channel structure CH extends closer to the second substrate 110 according to an aspect ratio. However, the embodiments are not necessarily limited thereto, and an arrangement, a structure, a shape, or the like of the channel structure CH may be variously modified.

The channel layer 140 may include a semiconductor material (e.g., polycrystalline silicon). The core insulation layer 142 may include any of various insulating materials such as, for example, silicon oxide, silicon nitride, silicon oxynitride, or a combination thereof.

The tunneling layer 152 may include an insulating material that is capable of tunneling a charge (e.g., silicon oxide, silicon oxynitride, or the like). The charge storage layer 154 may be used as a data storage region, and the charge storage layer 154 may include polycrystalline silicon, silicon nitride, or the like. The blocking layer 156 may include an insulating material that is capable of preventing an undesirable flow of charge into the gate line 130. The blocking layer 156 may include, for example, silicon oxide, silicon nitride, silicon oxynitride, a high dielectric constant material having a higher dielectric constant than silicon oxide, or a combination thereof. In an embodiment, the blocking layer 156 may include a first blocking layer 156a including a portion that extends horizontally along the gate line 130 and a second blocking layer 156b that extends vertically between the first blocking layer 156a and the charge storage layer 154. For example, the first blocking layer 156a may be in contact with the gate line 130 and the second blocking layer 156b might not be in contact with the gate line 130.

Materials, stacking structures, or the like of the channel layer 140, the core insulation layer 142, and the gate dielectric layer 150 may be variously modified, and the embodiments are not necessarily limited thereto.

The channel pad 144 may cover an upper surface of the core insulation layer 142 and may be electrically connected to the channel layer 140. The channel pad 144 may include a conductive material (e.g., polycrystalline silicon doped with a dopant), but the embodiments are not necessarily limited thereto.

In an embodiment, the gate stacking structure 120 may include a plurality of gate stacking structures 120a and 120b sequentially stacked. A number of stacked gate lines 130 may be increased and thus a number of memory cells may increase. In FIG. 1, it is illustrated as an example that the gate stacking structure 120 includes first and second gate stacking structures 120a and 120b. In some embodiments, the gate stacking structure 120 may include one gate stacking structure or three or more gate stacking structures.

When the plurality of gate stacking structures 120a and 120b are provided as in the above, the channel structure CH may include a plurality of channel structures CH1 and CH2 that respectively penetrate the plurality of gate stacking structures 120a and 120b and are electrically connected to each other. In a cross-sectional view, each of the plurality of channel structures CH1 and CH2 may have an inclined side surface such that a width of each of the plurality of channel structures CH1 and CH2 decreases as each of the plurality of channel structures CH1 and CH2 extends closer the second substrate 110 according to an aspect ratio. A bent portion due to a difference in widths of the plurality of channel structures CH1 and CH2 may be provided at a connection portion of the plurality of channel structures CH1 and CH2. In some embodiments, the plurality of channel structures CH1 and CH2 may have an inclined side surface that continuously extends without the bent portion. In FIG. 2, it is illustrated as an example that the gate dielectric layer 150, the channel layer 140, and the core insulation layer 142 of the plurality of channel structures CH1 and CH2 continuously extend to have an integral structure. In some embodiments, the gate dielectric layer 150, the channel layer 140, and the core insulation layer 142 of the plurality of channel structures CH1 and CH2 may be separately formed and be electrically connected to each other. In some embodiments, a separate channel pad 144 may be additionally disposed at a connection portion of the plurality of channel structures CH1 and CH2. As such, the embodiments are not necessarily limited to a shape of a plurality of channel structures CH1 and CH2.

In an embodiment, the gate stacking structure 120 may be divided into a plurality of portions in a plan view by a separation structure 146 extending in a direction crossing the second substrate 110 (e.g., in a direction perpendicular to the second substrate 110 or the Z-axis) and penetrates the gate stacking structure 120. An upper separation region 148 may be disposed at an upper portion of the gate stacking structure 120. In a plan view, the separation structure 146 and/or the upper separation region 148 may extend in a first direction (a Y-axis direction) and be spaced apart from each other at predetermined intervals in a second direction (an X-axis direction) that is transverse to the first direction.

The separation structure 146 and/or the upper separation region 148 may be filled with any of various insulating materials such as, for example, silicon oxide, silicon nitride, or silicon oxynitride. However, the embodiments are not necessarily limited thereto, and a structure, a shape, a material, or the like of the separation structure 146 or the upper separation region 148 may be variously modified.

The connection region 104 and the second wiring portion 180 may connect the gate stacking structure 120 and the channel structure CH in the cell array region 102 to the circuit region 200 or an external circuit. The connection region 104 may be at a periphery of the cell array region 102 and a partial portion of the second wiring portion 180 may be in the connection region 104.

The second wiring portion 180 may include a member electrically connecting the gate line 130, the channel structure CH, the horizontal conductive layers 112 and 114, and/or the second substrate 110 to the circuit region 200 or the external circuit. For example, the second wiring portion 180 may include a bit line 182, a gate contact portion 184, a source contact portion, a through plug 188, a contact via 180a connected to each of the bit line 182, the gate contact portion 184, the source contact portion, and/or a through plug 188, and a connection wiring 190 connecting the bit line 182, the gate contact portion 184, the source contact portion, the through plug 188, and the contact via 180a.

The bit line 182 may extend in the second direction (the X-axis direction) crossing the first direction in which the gate line 130 extends. The bit line 182 may be electrically connected to the channel structure CH (e.g., the channel pad 144) through the contact via 180a (e.g., a bit line contact via) that penetrates the cell insulation layer 132.

In the connection region 104, a plurality of gate contact portions 184 may penetrate the cell insulation layer 132 and be electrically connected to a plurality of gate lines 130, respectively, extended to the connection region 104. In the drawings, it is illustrated as an example that the plurality of gate lines 130 have a stair shape in one direction or a plurality of directions in the connection region 104, but the embodiments are not necessarily limited thereto. In the connection region 104, the source contact portion may penetrate the cell insulation layer 132 and be electrically connected to the horizontal conductive layers 112 and 114 and/or to the second substrate 110. The through plug 188 may penetrate the gate stacking structure 120 or may be at an outside of the gate stacking structure 120 and be electrically connected to the first wiring portion 230 of the circuit region 200.

In FIG. 1, it is illustrated as an example that each of the gate contact portions 184, the source contact portion, and/or the through plug 188 has an inclined side surface such that a width of each of the gate contact portion 184, the source contact portion, and/or the through plug 188 decreases as each of the gate contact portion 184, the source contact portion, and/or the through plug 188 goes to the second substrate 110 due to an aspect ratio in a cross-sectional view and a bent portion is provided at a boundary portion of the plurality of gate stacking structures 120a and 120b. However, the embodiments are not necessarily limited thereto. For example, in some embodiments, the source contact portion and/or the through plug 188 might not include the bent portion at the boundary portion of the plurality of gate stacking structures 120a and 120b.

In FIG. 1, it is illustrated as an example that the connection wiring 190 is a single layer on the same plane as the bit line 182 and a second insulation layer 192 is a single layer on the same plane as the bit line 182 and the connection wiring 190. However, this is not necessarily limited thereto. For example, the connection wiring 190 may include a plurality of wiring layers and may further include a contact via and connect with the bit line 182, the gate contact portion 184, the source contact portion, and/or the through plug 188.

The bit line 182 connected to the channel structure CH, the gate line 130, the horizontal conductive layers 112 and 114, and/or the second substrate 110 may be electrically connected to a circuit element 220 of the circuit region 200 through the second wiring portion 180 and the first wiring portion 230.

The circuit region 200 may include the first substrate 210, the circuit element 220 and the first wiring portion 230 on the first substrate 210.

The first substrate 210 may be a semiconductor substrate including a semiconductor material. For example, the first substrate 210 may be a semiconductor substrate including or formed of a semiconductor material or may be a semiconductor substrate in which a semiconductor layer is disposed on a base substrate. For example, the first substrate 210 may include single-crystalline or polycrystalline silicon, epitaxial silicon, germanium, silicon-germanium, silicon on insulator (SOI), germanium on insulator (GOI), or the like.

The circuit element 220 on the first substrate 210 may include circuit elements that control an operation of the memory cell structure in the cell region 100. For example, the circuit element 220 may include a peripheral circuit structure such as a decoder circuit 1110 (refer to FIG. 16), a page buffer 1120 (refer to FIG. 16), a logic circuit 1130 (refer to FIG. 16), or the like.

The circuit element 220 may include a plurality of transistors 260 and 270. In an embodiment, the plurality of transistors 260 and 270 may include a first transistor 260 and a second transistor 270, which will be described later in more detail. The circuit element 220 may include not only an active element such as the first and second transistor 260 or 270 or the like but also a passive element such as a capacitor, a resistor, an inductor, or the like.

The first wiring portion 230 on the first substrate 210 may be electrically connected to the circuit element 220. In an embodiment, the first wiring portion 230 may include a plurality of wiring layers 236 that are spaced apart from each other while interposing a first insulation layer 232 therebetween and are electrically connected by a contact via 234 and form a desired path. The wiring layer 236 or the contact via 234 may include conductive materials, and the first insulation layer 232 may include insulating materials. For example, a wiring layer 236, among the plurality of wiring layers 236, disposed at an uppermost portion adjacent to the cell region 100 may include or constitute a pad portion to which the gate contact portion 184, the source contact portion, a through plug 188, or the like is connected.

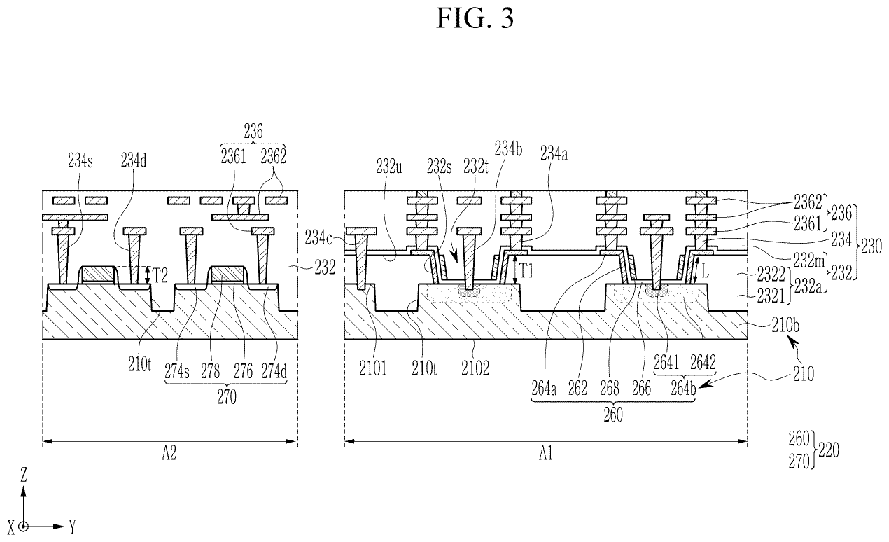

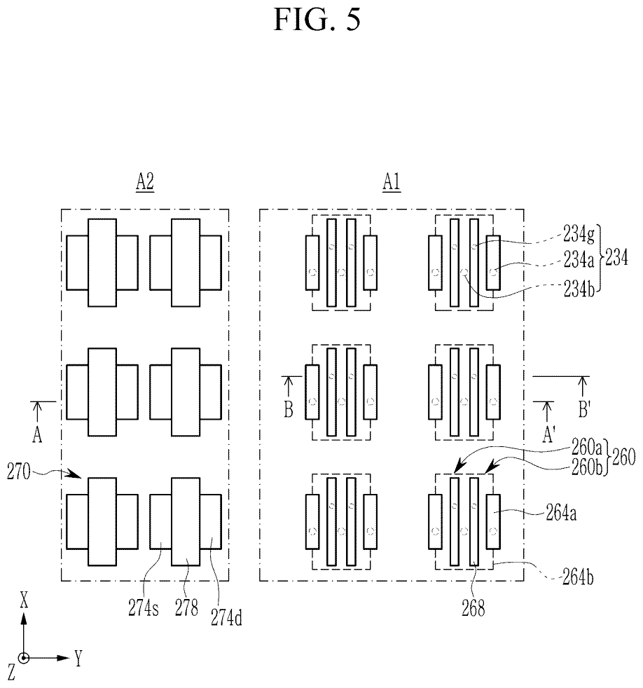

Referring to FIG. 3 to FIG. 5 together with FIG. 1 and FIG. 2, the first transistor 260 and the second transistor 270 will be described in more detail. FIG. 3 is a partial plan view schematically illustrating the circuit region 200 included in the semiconductor device 10 illustrated in FIG. 1. FIG. 4 is a cross-sectional view schematically illustrating a partial portion of the circuit region 200 included in the semiconductor device 10 illustrated in FIG. 1. FIG. 5 is a plan view schematically illustrating the first transistor 260 and the second transistor 270 included in the circuit region 200 illustrated in FIG. 3.

FIG. 4 is a cross-sectional view taken along a line B-B′ of FIG. 5. For simple illustration and a clear understanding, in FIG. 5, a first gate electrode 268 and first and second regions 264a and 264b of the first transistor 260 are mainly illustrated, and a gate contact 234g, a first contact 234a, and a second contact 234b electrically connected to the first gate electrode 268, the first region 264a, and the second region 264b, respectively, are illustrated as a dotted line.

Referring to FIG. 1 to FIG. 5, in an embodiment, the first substrate 210 may include a bulk region 210b, a second region 264b that is a partial portion of the first transistor 260, and source and drain regions 274s and 274d that are partial portions of the second transistor 270.

For example, the bulk region 210b may be or include a partial region of a semiconductor substrate having a first conductivity type (e.g., a p-type or an n-type). The second region 264b may be or include another region of the semiconductor substrate having a second conductivity type (e.g., an n-type or a p-type) opposite to the first conductive type. The source and drain regions 274s and 274d of the second transistor 270 may be or include yet another region of the semiconductor substrate having the second conductivity type (e.g., the n-type or the p-type) opposite to the first conductive type.

In an embodiment, the bulk region 210b and the second region 264b are portions including the same material (e.g. the same semiconductor material) and having the same crystal structure while having conductive types opposite to each other. The second region 264b may be formed by doping a dopant having an opposite conductive type to that of the bulk region 210b. Similarly, the bulk region 210b and the source and drain regions 274s and 274d are portions including the same material (e.g. the same semiconductor material) and having the same crystal structure while having conductive types opposite to each other. The source and drain regions 274s and 274d may be formed by doping a dopant having an opposite conductive type to that of the bulk region 210b.

For example, the bulk region 210b may include a single-crystalline semiconductor material (e.g., single-crystalline silicon) having a p-type, the second region 264b may include a single-crystalline semiconductor material (e.g., single-crystalline silicon) having an n-type, and the source and drain regions 274s and 274d may include a single-crystalline semiconductor material (e.g., single-crystalline silicon) having an n-type. For example, a p-type dopant may include boron, gallium, or the like, and an n-type dopant may include phosphorus, arsenic, or the like.

However, the embodiments are not necessarily limited thereto. A conductive well having a second conductivity type may be formed, and the source and drain regions 274s and 274d of the second transistor 270 having the first conductivity types may be included in the second transistor 270.

In an embodiment, the first substrate 210 may be provided with the plurality of transistors 260 and 270. The plurality of transistors 260 and 270 may include the first transistor 260, and the second transistor 270 having an operating voltage less than an operating voltage of the first transistor 260.

The first transistor 260 may be a high voltage (HV) transistor having a relatively higher operating voltage than that of the second transistor 270, and the second transistor 270 may be a low voltage (LV) transistor having a relatively lower operating voltage than that of the first transistor 260. For example, the second transistor 270 may have an operating voltage ranging from about 0.1 V to about 10 V, and the first transistor 260 may have an operating voltage greater than the operating voltage of the first transistor 260, for example, ranging from about 10 V to about 100 V. For example, the operating voltage of the first transistor 260 may be about 20V or more (e.g., about 20V to about 100V). However, the embodiments are not necessarily limited thereto.

The first transistor 260, which is the high voltage transistor, may be applied to a transistor that generates or transmits high voltage. For example, at least a part of transistors included in the decoder circuit 1110 (refer to FIG. 16), the page buffer 1120 (refer to FIG. 16), or the like may be configured as the first transistor 260. For example, the first transistor 260 may be connected to the through plug 188 which is electrically connected to the gate contact portion 184 and thus may apply voltage to the gate contact portion 184. The second transistor 270, which is the low voltage transistor, may have a high-speed operation property, and thus, may be applied to a transistor that requires high-speed operation.

The first transistor 260 may be disposed at a lower portion of the connection region 104 and the second transistor 270 may be disposed at a lower portion of the cell array region 102 in the drawings. In some embodiments, the first transistor 260 and the second transistor 270 may be disposed together at a lower portion of the cell array region 102. In some embodiments, the first transistor 260 and the second transistor 270 may be disposed together at a lower portion of the connection region 104. However, it is not necessarily limited thereto and positions of the first transistor 260 and the second transistor 270 may be modified.

In an embodiment, the first transistor 260 may include an insulation structure 232a, a channel region 262, the first and second regions 264a and 264b, a first gate insulating layer 266, and the first gate electrode 268. The second transistor 270 may include the source and drain regions 274s and 274d, a second gate insulating layer 276, and a second gate electrode 278. The first transistor 260 and the second transistor 270 may have different structures.

In an embodiment, the first transistor 260 may have a vertical structure. For example, the first transistor 260 may have a vertical channel structure. Here, the vertical structure may refer to a structure where the channel region 262 or the first gate electrode 268 includes a portion extending in a direction crossing a first surface 2101 or a second surface 2102 of the first substrate 210 (e.g., in a direction that is inclined or vertical to the first surface 2101 or the second surface 2102 of the first substrate 210). The vertical channel structure may refer to a structure where the channel region 262 includes a portion extending in a direction crossing the first surface 2101 or the second surface 2102 of the first substrate 210 (e.g., in a direction that is inclined or vertical to the first surface 2101 or the second surface 2102 of the first substrate 210).

In an embodiment, the second transistor 270 may have a structure different from a structure of the first transistor 260. For example, the second transistor 270 may have a planar structure. For example, the second transistor 270 may have a planar channel structure. Here, the planar type may refer to a structure where a channel portion or the second gate electrode 278 between the source and drain regions 274s and 274d include a portion parallel to the first surface 2101 or the second surface 2102 of the first substrate 210. Here, the planar channel type may refer to a structure where the channel portion between the source and drain regions 274s and 274d include a portion parallel to the first surface 2101 or the second surface 2102 of the first substrate 210.

In a first transistor region A1 where the first transistor 260 is provided, the insulation structure 232a may be disposed on the first substrate 210. The channel region 262 and/or the first gate electrode 268 may be disposed adjacent to the insulation structure 232a. For example, the channel region 262 and/or the first gate electrode 268 may be formed on a side surface of the insulation structure 232a. The insulation structure 232a may include a first portion 2321 and a second portion 2322. The second portion 2322 (may have a thickness T1 of the insulation structure 232a with a predetermined value so that the channel region 262 that corresponds with a length of the insulation structure 232a. The first portion 2321 may fill a trench 210t of the first substrate 210.

In an embodiment, the first portion 2321 may be a device separation portion or a shallow trench insulation that separates the first transistors 260. The channel region 262, the first gate electrode 268, or the like may be disposed on a side surface of the second portion 2322. The first portion 2321 and the second portion 2322 may include the same material or different materials. In a final structure, a boundary between the first portion 2321 and the second portion 2322 may be seen or confirmed or might not be seen or confirmed.

The channel region 262 may extend in a direction crossing the first substrate 210 disposed on the side surface of the insulation structure 232a (e.g., a side surface of the insulation structure 232a adjacent to a recess 232t). For example, the channel region 262 may include a side extension portion extending in a direction that is inclined or vertical to the first surface 2101 or the second surface 2102 of the first substrate 210.

The insulation structure 232a may include insulating materials such as, for example, oxide, nitride, or oxynitride. For example, the insulation structure 232a may include an insulating material such as silicon oxide, silicon nitride, or silicon oxynitride. However, the embodiments are not necessarily limited thereto and a material or the like of the insulation structure 232a may be modified.

In an embodiment, the channel region 262 may be or include a first semiconductor layer including a semiconductor material. The channel region or the first semiconductor layer may be a separate layer from the first substrate 210 and have a material or a crystal structure different from the first substrate 210. The first semiconductor layer of the channel region 262 may have a first conductivity type (e.g., a p-type or an n-type) that is the same as the bulk region 210b of the first substrate 210. A dopant included in the channel region 262 may be the same as or different from a dopant included in the bulk region 210b of the first substrate 210. For example, a p-type dopant may include boron, gallium, or the like, and an n-type dopant may include phosphorus, arsenic, or the like. For example, the channel region 262 may be or include a polycrystalline semiconductor layer having the first conductivity type. For example, the channel region 262 may include polycrystalline silicon, polycrystalline germanium, polycrystalline silicon-germanium, or the like.

The embodiments are not necessarily limited to the material of the channel region 262, the crystal structure of the channel region 262, the dopant doped to the channel region 262, or the like.

Source and drain regions of the first transistor 260 may be electrically connected to the channel region 262, respectively. In an embodiment, the first region 264a that is one of the source and drain regions of the first transistor 260 and the second region 264b that is the other of the source and drain regions of the first transistor 260 may have different materials or different crystal structures.

For example, the first region 264a may be or include a second semiconductor layer including a semiconductor material. The first region 264 or the second semiconductor layer may be a separate layer from the first substrate 210 and have a material or a crystal structure different from the first substrate 210. Here, the second semiconductor layer of the first region 264a may have a second conductivity type (e.g., an n-type or a p-type) that is opposite to the channel region 262. For example, the first region 264a may be or include a polycrystalline semiconductor layer having a second conductivity type. For example, the first region 264a may include polycrystalline silicon, polycrystalline germanium, polycrystalline silicon-germanium, or the like.

The first semiconductor layer of the channel region 262 and the second semiconductor layer of the first region 264a may be connected to each other and have a layer shape. The first semiconductor layer of the channel region 262 and the second semiconductor layer of the first region 264a may include the same semiconductor material and may have substantially similar thicknesses. For example, a thickness difference between the first semiconductor layer of the channel region 262 and the second semiconductor layer of the first region 264a may be about 10% or less of the thickness of the first semiconductor layer of the channel region 262 or the second semiconductor layer of the first region 264a.

The channel region 262 and the first region 264a may have the same material and the same crystal structure while having conductivity types that are opposite to each other. The first region 264a may be formed by doping a dopant having an opposite conductive type to that of the channel region 262. For example, the channel region 262 may include a polycrystalline semiconductor material (e.g., polycrystalline silicon) having a p-type, and the first region 264a may include a polycrystalline semiconductor material (e.g., polycrystalline silicon) having an n-type.

The second region 264b may be adjacent to the first substrate 210 and may be or include a partial portion of the first substrate 210. Accordingly, the second region 264b may have a same conductive type as the first region 264a while having a different material or a different crystal structure from the first region 264a.

In an embodiment, a thickness of the channel region 262 or a thickness of the first region 264a may be less than a thickness of the first substrate 210. The thickness of the channel region 262 or the thickness of the first region 264a may be the minimum thickness measured in a direction vertical to a side surface 232s or an upper surface 232u of the insulation structure 232a. The thickness of the first substrate 210 may be the minimum thickness measured in a direction (the Z-axis direction) vertical to the first substrate 210. For example, the thickness of the channel region 262 or the thickness of the first region 264a may be 200 nm or less. Thereby, manufacturing time of the channel region 262 or the first region 264a may be reduced. However, the embodiments are not necessarily limited thereto, and the thickness of the channel region 262 or the thickness of the first region 264a may be greater than 200 nm.

The thickness of the channel region 262 or the thickness of the first region 264a may be different from the thickness of the second region 264b. The thickness of the second region 264b may be the maximum thickness measured in a direction (the Z-axis direction) vertical to the first substrate 210. This is because the channel region 262 or the first region 264a is in a semiconductor layer and the second region 264b is in the first substrate 210. For example, the thickness of the channel region 262 or the thickness of the first region 264a may be less than the thickness of the second region 264b. Thereby, manufacturing time of the channel region 262 or the first region 264a may be reduced and the second region 264b may be stably formed to have a sufficient size. However, the embodiments are not necessarily limited thereto. In some embodiments, the thickness of the channel region 262 or the thickness of the first region 264a may be the same as or greater than the thickness of the second region 264b.

In an embodiment, the semiconductor layer may be disposed on the side surface 232s and the upper surface 232u of the insulation structure 232a. The first region 264a or the second semiconductor layer may be disposed on the upper surface 232u of the insulation structure 232a, and the channel region 262 or the first semiconductor layer may be disposed adjacent to the side surface 232s of the insulation structure 232a.

The channel region 262 or the first semiconductor layer may extend from a first side adjacent to the upper surface 232u of the insulation structure 232a to a second side adjacent to the first substrate 210 on the insulation structure 232a. For example, a bottom end of the channel region 262 may be in contact with the first substrate 210. The first side of the channel region 262 may be connected to the first region 264a on the upper surface 232u of the insulation structure 232a, and the second side of the channel region 262 may be connected to one surface of the first substrate 210 or the second region 264b.

In an embodiment, the second region 264b may include a low concentration region 2642 having a relatively lower doping concentration, and a contact region 2641 having a doping concentration higher than a doping concentration of the low concentration region 2642. The contact region 2641 may be a region having a relatively higher doping concentration and may be referred to as a high concentration region. The second contact 234b may be connected to the contact region 2641, thereby reducing contact resistance of the second contact 234b. The low concentration region 2642 may be formed at a region other than the contact region 2641. Accordingly, a depletion region may be stably formed and performance of the first transistor 260 may be enhanced. In an embodiment, the second side of the channel region 262 may be connected to the low concentration region 2642.

The first gate insulating layer 266 may be disposed adjacent to the channel region 262. For example, the first gate insulating layer 266 may be in contact with the channel region 262. The first gate insulating layer 266 may include at least one of oxide, nitride, oxynitride, a high dielectric constant material having a higher dielectric constant than silicon oxide, a low dielectric constant material having a lower dielectric constant than silicon oxide, or a combination thereof. For example, the first gate insulating layer 266 may include at least one of silicon oxide, silicon nitride, silicon oxynitride, hafnium oxide, aluminum oxide, and tantalum oxide. The first gate insulating layer 266 may include an insulation layer or a plurality of insulating layers.

It is illustrated as an example in the drawing that the first gate insulating layer 266 may be disposed on an entirety of a region including the first substrate 210, the channel region 262, the first region 264a, and the upper surface 232u of the insulation structure 232a. Thereby, the first gate insulating layer 266 may be formed without an additional patterning process. However, the embodiments are not necessarily limited thereto. In some embodiments, the first gate insulating layer 266 may be disposed on a partial portion of the region including the first substrate 210, the channel region 262, the first region 264a, and the upper surface 232u of the insulation structure 232a. Even though a boundary of the first gate insulating layer 266 is illustrated in the drawing for a clear understanding, the boundary of the first gate insulating layer 266 might not be seen or confirmed in a final structure.

In an embodiment, the channel region 262 of the first transistor 260 may include a portion (e.g., the side extension portion) at least partially surrounded by the insulation structure 232a and the first gate insulating layer 266. For example, four outer surfaces of a partial portion (i.e., the side extension portion) of the channel region 262 on the side surface 232s of the insulation structure 232a may be surrounded by the insulation structure 232a and the first gate insulating layer 266.

The first gate electrode 268 may be disposed on the first gate insulating layer 266 disposed on the channel region 262. The first gate electrode 268 may extend along a direction crossing the first substrate 210 on the channel region 262 and the first gate insulating layer 266 on the side surface 232s of the insulation structure 232a (e.g., the side surface of the insulation structure 232a adjacent to the recess 232t). For example, the first gate electrode 268 may include a side extension portion extending along a direction that is inclined or vertical to the first surface 2101 or the second surface 2102 of the first substrate 210.

The first gate electrode 268 may include a conductive material. For example, the first gate electrode 268 may include at least one of metal, a metal alloy, metal nitride, metal silicide, and a doped semiconductor material. Here, the metal or the metal alloy included in the first gate electrode 268 may include at least one of titanium, tungsten, molybdenum, aluminum, copper, cobalt, tantalum, and ruthenium. The metal nitride included in the first gate electrode 268 may include at least one of titanium nitride, tungsten nitride, molybdenum nitride, and tantalum nitride. The first gate electrode 268 may further include metal oxide or metal oxynitride in which the above material is oxidized. The doped semiconductor material may include a semiconductor material (e.g., a polycrystalline semiconductor material) doped with an n-type or a p-type dopant.

An interlayer insulation layer 232m may be disposed on the insulation structure 232a, the channel region 262 and the first region 264a, the first gate insulating layer 266, and first gate electrode 268 disposed on the first substrate 210. The contact via 234 may penetrate through the first gate insulating layer 266 and/or the interlayer insulation layer 232m. The contact via 234 may include a gate contact 234g connected to the first gate electrode 268, a first contact 234a connected to the first region 264a, and a second contact 234b connected to the second region 264b. The contact via 234 may further include a body contact 234c connected to the first substrate 210. A first wiring layer 2361 connected to the contact via 234 connected to the first transistor 260 may be disposed on the interlayer insulation layer 232m.

In the first transistor region A1, the first wiring layer 2361 may include a first electrode wiring connected to the first region 264a through the first contact 234a, a second electrode wiring connected to the second region 264b through the second contact 234b, and a first gate electrode wiring connected to the first gate electrode 268 through the gate contact 234g.

One or a plurality of interlayer insulation layers 232m and one or a plurality of second wiring layers 2362 may be further disposed on the first wiring layer 2361.

In a plan view, the gate contact 234g connected to the first gate electrode 268 may be disposed at a first position (an upper portion of FIG. 5) along the X-axis direction, and the first contact 234a connected to the first region 264a and the second contact 234b connected to the second region 264b may be disposed at a second position (a lower portion of FIG. 5) different from the first position in the one direction (the X-axis direction). Thereby, the gate contact 234g, the first contact 234a, and the second contact 234b may be stably positioned.

In an embodiment, the first region 264a that is the partial portion of the semiconductor layer in the first transistor 260 may be a source region, and the second region 264b that is the partial portion of the first substrate 210 may be a drain region. In this instance, the through plug 188 connected to the gate line 130 may be electrically connected to the first region 264a. However, the embodiments are not necessarily limited thereto.

For example, the second region 264b may be shared by a pair of first transistors 260a and 260b adjacent to each other in one direction (the Y-axis direction). For example, one second region 264b may be included in the pair of first transistors 260a and 260b, and the pair of first transistors 260a and 260b may have a symmetrical structure in the one direction (the Y-axis direction). Thereby, a size of the second transistor 270 may be effectively reduced.

The trench 210t may be disposed in the second transistor region A2 where the second transistor 270 is provided, and the first insulation layer 232 may fill the trench 210t. In an embodiment, the trench 210t filled with the first insulation layer 232 may be a device separation portion or a shallow trench insulation that separates the second transistors 270.

The first insulation layer 232 in the second transistor region A2 may include insulating materials. For example, the first insulation layer 232 may include an insulating material such as oxide, nitride, or oxynitride. For example, the first insulation layer 232 may include an insulating material such as silicon oxide, silicon nitride, or silicon oxynitride. However, the embodiments are not necessarily limited thereto and a material or the like of the first insulation layer 232 may be modified.

It is illustrated as an example in the drawing that a second width of the trench 210t in the second transistor region A2 is less than a first width of the trench 210t in the first transistor region A1. Thereby, in the first transistor region A1 where the first transistor 260 of a high voltage transistor is positioned, an active region of the first transistor may be stably separated. However, the embodiments are not necessarily limited thereto. In some embodiments, the first width of the trench 210t in the first transistor region A1 may be the same or less than the second width of the trench 210t in the second transistor region A2.

In an embodiment, the second transistor 270 may include a second gate insulating layer 276, a second gate electrode 278, and source and drain regions 274s and 274d. The second gate insulating layer 276 may be disposed horizontally on the first substrate 210. The second gate electrode 278 may be disposed horizontally on the second gate insulating layer 276. The source and drain regions 274s and 274d may be disposed at portions of the first substrate 210 that are at both sides of the second gate electrode 278 in a plan view. The second transistor 270 may further include a gate capping layer and/or a gate spacer.

In the second transistor 270, the channel portion may include or be formed of a partial portion of the bulk region 210b of the first substrate 210 at a lower portion of the second gate electrode 278 and the second gate insulating layer 276 between the source and drain regions 274s and 274d. The channel portion of the second transistor 270 may be different from the channel region 262 of the first transistor 260 that is a separate one from the first substrate 210 and is on the side surface 232s of the insulation structure 232a.

The second gate insulating layer 276 may horizontally extend to be parallel to the first surface 2101 or the second surface 2102 of the first substrate 210. The second gate insulating layer 276 may be different from the first gate insulating layer 266 including the portion that is vertical to or inclined to the first surface 2101 or the second surface 2102 of the first substrate 210. A thickness of the second gate insulating layer 276 may be less than a thickness of the first gate insulating layer 266. This is because the first transistor 260 is the high voltage transistor and the second transistor 270 is the low voltage transistor. In some embodiments, the thickness of the second gate insulating layer 276 may be the same as or greater than the thickness of the first gate insulating layer 266.

The second gate insulating layer 276 may include at least one of oxide, nitride, oxynitride, a high dielectric constant material having a higher dielectric constant than silicon oxide, and a low dielectric constant material having a lower dielectric constant than silicon oxide. For example, the second gate insulating layer 276 may include at least one of silicon oxide, silicon nitride, silicon oxynitride, hafnium oxide, aluminum oxide, and tantalum oxide. The second gate insulating layer 276 may include one insulation layer or may include a plurality of insulation layers.

The second gate electrode 278 may include a conductive material. For example, the second gate electrode 278 may include at least one of metal, a metal alloy, metal nitride, metal silicide, and a doped semiconductor material. The metal or the metal alloy included in the second gate electrode 278 may include at least one of titanium, tungsten, molybdenum, aluminum, copper, cobalt, tantalum, and ruthenium. The metal nitride included in the second gate electrode 278 may include at least one of titanium nitride, tungsten nitride, molybdenum nitride, and tantalum nitride. The second gate electrode 278 may further include metal oxide or metal oxynitride in which the above material is oxidized. The doped semiconductor material may include a semiconductor material (e.g., a polycrystalline semiconductor material) doped with an n-type or a p-type dopant.

A gate capping layer may be disposed on the second gate electrode 278, and a gate spacer may be disposed on a side surface of the second gate electrode 278. The gate capping layer may act as a mask layer in a process forming the second gate insulating layer 276 and the second gate electrode 278. The gate spacer may be disposed on the side surface of the second gate electrode 278 and insulate the second gate electrode 278 and the source and drain regions 274s and 274d. For example, the gate spacer may be at least disposed at both side surfaces of the second gate electrode 278 in a transverse direction (the Y-axis direction) that is transverse to an extension direction of the second gate electrode 278, and may extend in the extension direction (the X-axis direction) of the second gate electrode 278. The gate spacer may be disposed on the side surface of the gate capping layer, or the gate capping layer may be disposed on the gate spacer.

The gate capping layer or the gate spacer may include any of various materials such as oxide, nitride, oxynitride, or the like. For example, the gate capping layer or the gate spacer may include at least one of silicon oxide, silicon nitride, and silicon oxynitride. The gate capping layer or the gate spacer may include one insulation layer or may include a plurality of insulation layers.

However, the embodiments are not necessarily limited thereto. The second gate insulating layer 276, the second gate electrode 278, the gate capping layer, the gate spacer, and/or the source and drain regions 274s and 274d may have any of various materials, structures, or the like.

The interlayer insulation layer 232m may be disposed on the second gate insulating layer 276 and the second gate electrode 278 disposed on the first substrate 210. The contact via 234 may penetrate through the interlayer insulation layer 232m. The contact via 234 may include a gate contact connected to the second gate electrode 278, and source and drain contacts 234s and 234d connected to the source and drain regions 274s and 274d. The first wiring layer 2361 connected to the contact via 234 which is connected to the second transistor 270 may be disposed on the interlayer insulation layer 232m.

In the second transistor region A2, the first wiring layer 2361 may include a source electrode wiring connected to the source region 274s through the source contact 234s, a drain electrode wiring connected to the drain region 274d through the drain contact 234d, and a second gate electrode wiring connected to the first gate electrode 278 through the gate contact. For example, the first wiring layer 2361 including the source electrode wiring, the drain electrode wiring, and the second gate electrode wiring in the second transistor region A2 may be disposed on the same plane or on the same layer as the first wiring layer 2361 including the first electrode wiring, the second electrode wiring, and the first gate electrode wiring in the first transistor region A1.

One or a plurality of interlayer insulation layers 232m and one or a plurality of second wiring layers 2362 may be further disposed on the first wiring layer 2361.

In an embodiment, the thickness T1 of the insulation structure 232a, a length L of the side surface 232s of the insulation structure 232a, or a length of the channel region 262 in the first transistor 260 may be greater than a thickness T2 of the second gate electrode 278 in the second transistor 270. Thereby, a channel length of the channel region 262 of the first transistor 260 may be sufficiently secured.

Here, the thickness T1 of the insulation structure 232a may refer to a thickness of the second portion 2322 on the first surface 2101 of the first substrate 210 where the trench 210t is not provided. The thickness T1 of the insulation structure 232a may be measured in a direction (the Z-axis direction) vertical to the first substrate 210. The length L of the side surface 232s of the insulation structure 232a may refer to the minimum length among lengths measured along the side surface 232s of the insulation structure 232a. The length of the channel region 262 may be the minimum length among lengths along the channel region 262 between the first region 264a and the second region 264b or between the first region 264a and the first substrate 210. The thickness T2 of the second gate electrode 278 may be a thickness measured in a direction (the Z-axis direction in the drawing) vertical to the first substrate 210.

In an embodiment, the thickness T1 of the insulation structure 232a, the length L of the side surface 232s of the insulation structure 232a, or the length of the channel region 262 in the first transistor 260 may be greater than a distance between the source region 274s and the drain region 274d (i.e., the length of the channel portion) in the second transistor 270. Thereby, the channel length of the channel region 262 of the first transistor 260 may be sufficiently secured. Here, the length of the channel portion or the distance between the source region 274s and the drain region 274d or between the first region 264a and the first substrate 210 in the second transistor 270 may refer to the minimum distance.

According to an embodiment, the first transistor 260 that is the high voltage transistor has a vertical structure (e.g., a vertical channel structure) and thus a size or an area of the first transistor 260 may be reduced by 3-dimensional (3D) integration. Thereby, an integration degree may be enhanced.

The second region 264b that is one of the source and drain regions of the first transistor 260 may be or include a partial portion of the first substrate 210. Thus, the first transistor 260 (for example, the channel region 262) may have a structure coupled or connected to the first substrate 210 having a large volume. Thereby, problems by a floating body effect may be prevented or suppressed and punch-through may be prevented from occurring in an off state. Accordingly, performance of the first transistor 260 where high voltage is generated or transmitted may be enhanced.

On the other hand, in a high voltage transistor having the conventional vertical structure, a source region, a channel region, and a drain region may be separate from the semiconductor substrate to form a floating body. Then, punch-through may occur in an off state by a depletion region in a high voltage transistor where high voltage is generated or transmitted, and thus, the high voltage transistor might not be suitably driven as a high voltage transistor.

In an embodiment, the circuit region 200 including the first substrate 210, the first transistor 260, and the second transistor 270 may be included in the semiconductor device 10 including the cell region 100 having the memory cell structure. For example, the semiconductor device 10 including the circuit region 200 according to an embodiment may be a flash memory device. This is because the high voltage transistor or the second transistor 270 of the flash memory device is operated by a higher voltage than a transistor of another memory device or another semiconductor device. Accordingly, performance and an integration degree may be enhanced in the flash memory device including the high voltage transistor or the second transistor 270 operated by large operating voltage. For example, the second transistor 270 may be included in the flash memory device including large numbers of gate lines 130 and first transistors 260 and increase data storage capacity, thereby greatly enhancing an integration degree.

In the drawings, it is illustrated as an example that the extension direction of the first or second gate electrode 268 or 278 (the X-axis direction in the drawings) is perpendicular to an extension direction of the gate line 130. Additionally, it is illustrated as an example that a direction where the source and drain regions 274s and 274d are positioned or the first and second region 264a and 264b are positioned (the Y-axis direction) is parallel to the extension direction of the gate line 130. However, embodiments are not necessarily limited thereto. In some embodiments, the extension direction of the first or second gate electrode 268 or 278 (the X-axis) may be parallel to an extension direction of the gate line 130, and the direction where the source and drain regions 274s and 274d are positioned or the first and second region 264a and 264b are positioned (the Y-axis direction) may be transverse to the extension direction of the gate line 130.

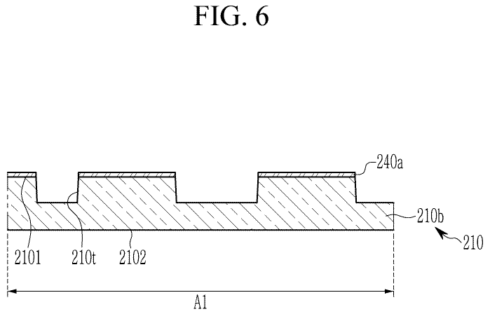

An example of a manufacturing method of a semiconductor device 10 having the above structure will be described in detail with reference to FIG. 6 to FIG. 12 together with FIG. 1 to FIG. 5. To the extent that an element is not described in detail below, it may be understood that the element is at least similar to a corresponding element that has been described elsewhere within the present disclosure. A portion which is not described in the above will be described in detail.

FIG. 6 to FIG. 12 are cross-sectional views illustrating a manufacturing method of a semiconductor device according to an embodiment. In FIG. 6 to FIG. 12, a first transistor 260 in a circuit region 200 of a semiconductor device 10 is mainly illustrated, and a manufacturing method of the first transistor 260 in the circuit region 200 of the semiconductor device 10 will be mainly described below.

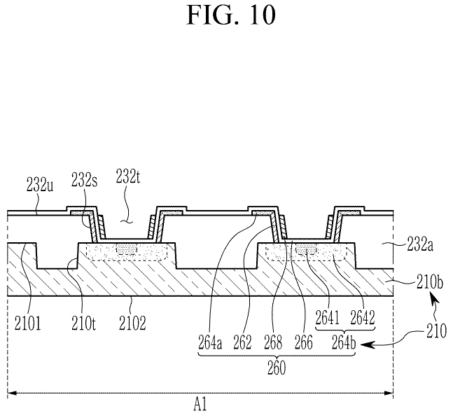

As illustrated in FIG. 6, a first mask layer 240a exposing a boundary of a plurality of first transistors 260 (refer to FIG. 10) may be formed on a first surface 2101 of a first substrate 210. A trench 210t may be formed by etching a partial portion of the first substrate 210 using the first mask layer 240a at the first surface 2101 of the first substrate 210. During an etching process, processes such as dry etching may be applied. In this instance, the first substrate 210 may consist of or include a bulk region 210b having a first conductivity type.

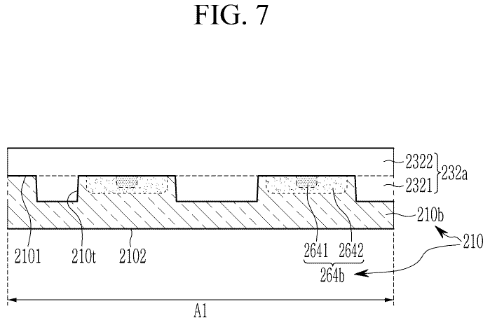

Subsequently, as illustrated in FIG. 7, an insulation structure 232a including a first portion 2321 filling the trench 210t may be formed. The insulation structure 232a may include the first portion 2321 filling the trench 210t of the first substrate 210 and a second portion 2322 disposed on the first surface 2101 of the first substrate 210 with a predetermined thickness.

In an embodiment, a process for forming the first portion 2321 filling the trench 210t of the first substrate 210 and a process for forming the second portion 2322 may be separately performed. For example, an insulating material layer may be formed and fill the trench 210t of the first substrate 210. Then, a chemical mechanical polishing process may be performed and form the first portion 2321. The first mask layer 240a may be removed during the chemical-mechanical polishing process, but the embodiments are not necessarily limited thereto. An insulation material layer may be formed on the first substrate 210 to form the second portion 2322. In some embodiments, after forming the second portion 2322, a chemical mechanical polishing process may be performed.

Any of various processes, for examples, a deposition processes (e.g., chemical vapor deposition or physical vapor deposition), or the like may be used as a process for forming the insulating material layer.

In an embodiment, between the process of forming the first portion 2321 and the process of forming the second portion 2322, a process of forming a second region 264b of the first transistor 260 may be performed. The second region 264b may be formed by doping a second conductivity type dopant to a partial portion of the first substrate 210. However, the process is not necessarily limited thereto and the process of forming the second region 264b may be performed by any of various doping processes. For example, the second region 264b may be performed after the process of forming a recess 232t.

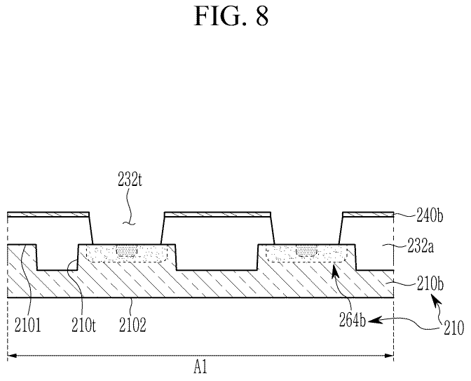

Subsequently, as illustrated in FIG. 8, a second mask layer 240b exposing a region of the first substrate 210 between the trenches 210t of the first substrate 210 may be formed on the insulation structure 232a. A recess 232t may be formed by etching a partial portion of the insulation structure 232a using the second mask layer 240b disposed at an upper portion of the insulation structure 232a. During an etching process, processes such as dry etching may be applied.

It is illustrated as an example in FIG. 7 and FIG. 8 that entire second portion 2322 is formed and then the recess 232t is formed by a patterning process, but the embodiments are not necessarily limited thereto. For example, the second portion 2322 having the recess 232t may be formed during the process of forming the second portion 2322.

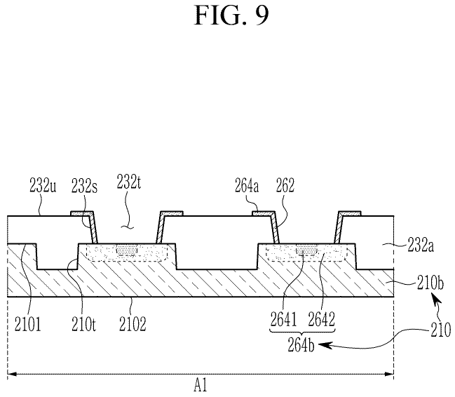

Subsequently, as illustrated in FIG. 9, a channel region 262 of the first transistor 260 and a first region 264a may be formed.

In an embodiment, a semiconductor layer may be formed on an upper surface 232u and a side surface 232s of the insulation structure 232a, a portion of the first surface 2101 of the first substrate 210 exposed by the recess 232t. For example, the semiconductor layer may be formed by a method such as deposition or the like. Then, a portion other than regions corresponding to the channel region 262 and the first region 264a may be etched, and thus, a portion of the semiconductor layer corresponding to the channel region 262 and the first region 264a may be remained. For example, the semiconductor layer may be patterned by dry etching using the mask layer. However, the embodiments are not necessarily limited thereto.

By the patterning process, the semiconductor layer may include a portion on the upper surface 232u and the side surface 232s of the insulation structure 232a at one side of the recess 232t, and another portion on the upper surface 232u and the side surface 232s of the insulation structure 232a at the other side of the recess 232t. Thereby, the portion at the one side of the recess 232t may be included in one first transistor 260, and another portion at the other side of the recess 232t may be included in another first transistor 260. Accordingly, a process may be simplified and a size of the first transistor 260 may be reduced.

For example, a first semiconductor layer having a first conductivity type dopant is formed in a process of forming the semiconductor layer, and then, the first region 264a may be formed by doping a second conductivity type dopant to a partial portion corresponding to the first region 264a. A remaining portion of the first semiconductor layer where the second conductivity type dopant is not doped may constitute the channel region 262. Thereby, properties of the channel region 262 may be maintained and a process may be simplified. However, the embodiments are not necessarily limited thereto.

In some embodiments, a second semiconductor layer having the second conductivity type dopant is formed in a process of forming the semiconductor layer, and then, the channel region 262 may be formed by doping the first conductivity type dopant to a partial portion corresponding to the channel region 262. In some embodiments, after an undoped semiconductor layer (e.g., the semiconductor layer not including a dopant) is formed in a process of forming the semiconductor layer, the channel region 262 and the first region 264a may be formed by doping the first conductivity type dopant to a partial portion corresponding to the channel region 262 and doping the second conductivity type dopant to a partial portion corresponding to the first region 264a.

Subsequently, as illustrated in FIG. 10, a first gate insulating layer 266 and a first gate electrode 268 may be formed.

The first gate insulating layer 266 may be formed on the first surface 2101 of the first substrate 210 and cover the insulation structure 232a, the channel region 262, and the first region 264a. The first gate insulating layer 266 may be formed by a method such as deposition or the like.

The first gate electrode 268 may be formed on the first gate insulating layer 266. The entire first gate electrode 268 may be formed, and then, a portion other than a portion on the side surface 232s of the insulation structure 232a may be removed by a patterning process. Thereby, the first gate electrode 268 may be formed on the channel region 262 and the first gate insulating layer 266 on the side surface 232s of the insulation structure 232a. The first gate electrode 268 may be formed by methods such as deposition, plating, or the like. The patterning process of the first gate electrode 268 may be performed by dry etching using a mask layer. However, the embodiments are not necessarily limited thereto.

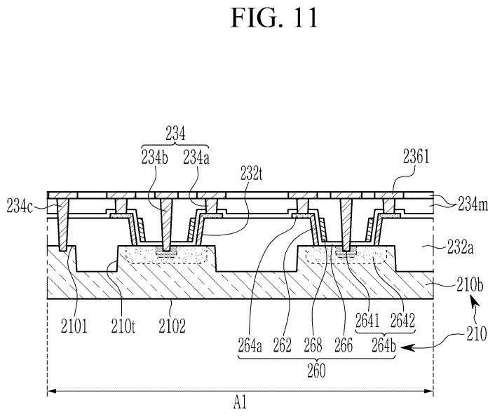

Subsequently, as illustrated in FIG. 11, an interlayer insulation layer 232m being on the insulation structure 232a and filling the recess 232t may be formed on the first gate insulating layer 226. For example, an insulating material may be formed and fill the recess 232t. Then, chemical mechanical polishing process may be performed and form the interlayer insulation layer 232m.

A contact via 234 penetrating through the first gate insulating layer 266 and/or the interlayer insulation layer 232m and a first wiring layer 2361 connected to the contact via 234 may be formed. In this instance, the contact via 234 may include a gate contact 234g (refer to FIG. 4) connected to the first gate electrode 268, a first contact 234a connected to the first region 264a, and a second contact 234b connected to the second region 264b. The contact via 234 may further include a body contact 234c connected to the first substrate 210. For example, the contact via 234 may be formed by filling a conductive material to a penetrating portion. For example, a first wiring layer 2361 may be formed by forming another interlayer insulation layer 232m exposing the contact via 234 and then performing a chemical mechanical polishing process. However, the embodiments are not necessarily limited thereto and modifications are possible.

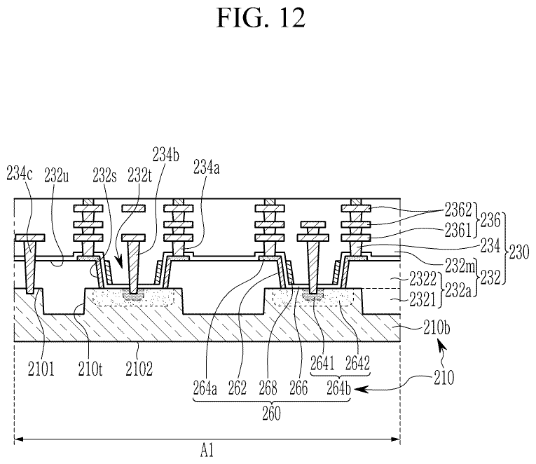

Subsequently, as illustrated in FIG. 12, a first wiring portion 230 may be formed by further forming one or a plurality of interlayer insulation layers 232m and one or a plurality of second wiring layers 2362 disposed on the first wiring layer 2361.

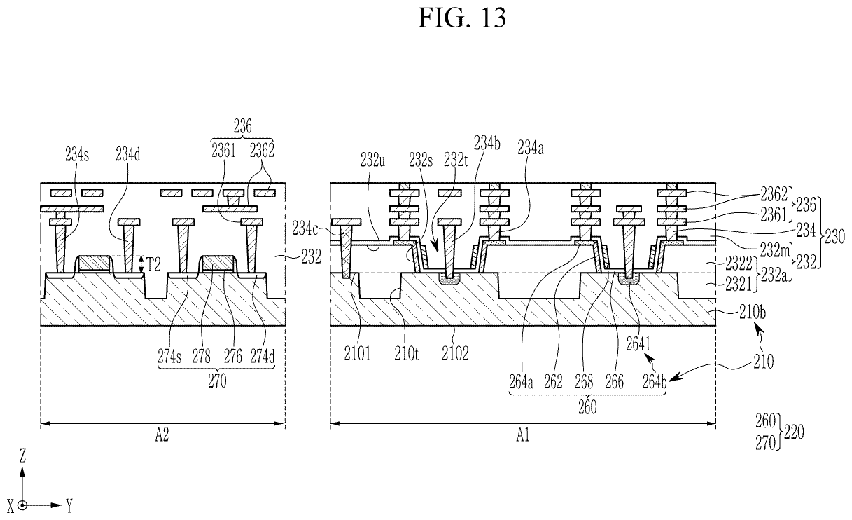

Hereinafter, referring to FIG. 13 to FIG. 15, semiconductor devices according to other embodiments different from the above embodiment will be described in more detail. To the extent that an element is not described in detail below, it may be understood that the element is at least similar to a corresponding element that has been described elsewhere within the present disclosure. A portion which is not described in the above will be described in detail.

FIG. 13 is an enlarged plan view illustrating a partial portion of a semiconductor device according to an embodiment. In FIG. 13, a portion corresponding to a portion illustrated in FIG. 3 is illustrated.

Referring to FIG. 13, in a first transistor 260 according an embodiment, a second region 264b may include a contact region 2641 that is locally formed and correspond to a second contact 234b while not including a low concentration region 2642 (refer to FIG. 3). In this instance, a channel region 262 of the first transistor 260 may be connected to a bulk region 210b of a first substrate 210. Thereby, a size or an area of a doping region of the first substrate 210 may be reduced.

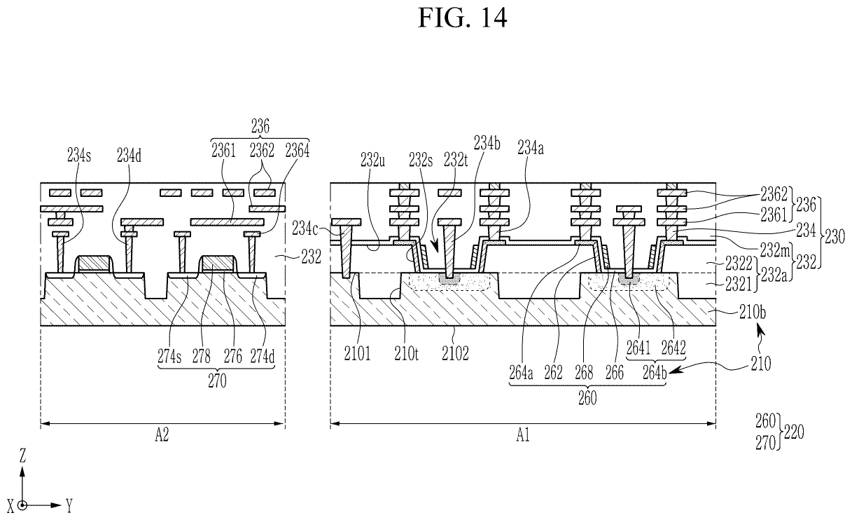

FIG. 14 is an enlarged plan view illustrating a partial portion of a semiconductor device according to an embodiment. In FIG. 14, a portion corresponding to a portion illustrated in FIG. 3 is illustrated.

Referring to FIG. 14, in an embodiment, a first wiring layer 2361 including a gate contact 234g (refer to FIG. 4), a first contact 234a, and a second contact 234b connected to a first gate electrode 268, a first region 264a, and a second region 264b, respectively, may be included in a first transistor 260. In the first transistor region A1, the first wiring layer 2361 may be a wiring layer disposed closest to the first transistor 260 among a plurality of wiring layers 236. For example, in the first transistor region A1, the first wiring layer 2361 may be disposed below the second wiring layer 2362.

In the first transistor region A1, the first wiring layer 2361 may include a first electrode wiring connected to the first region 264a through the first contact 234a, a second electrode wiring connected to the second region 264b through the second contact 234b, and a first gate electrode wiring connected to the first gate electrode 268 through the gate contact 234g.

In a second transistor region A2, an additional wiring layer 2364 may be provided between the first wiring layer 2361 and the second transistor 270. The first wiring layer 2361 in the second transistor region A2 may be disposed on the same layer or the same plane as the first wiring layer 2361 in the first transistor region A1. Thereby, among the plurality of wiring layers 236 in the second transistor region A2, the additional wiring layer 2364 may be disposed closer to the second transistor 270 than the first wiring layer 2361. For example, the additional wiring layer 2364 in the second transistor region A2 may be disposed below the first wiring layer 2361.

In the second transistor region A2, the additional wiring layer 2364 may include a source electrode wiring connected to a source region 274s through a source contact 234s, a drain electrode wiring connected to a drain region 274d through a drain contact 234d, and a second gate electrode wiring connected to a second gate electrode 278 through a gate contact. For example, in an embodiment, the additional wiring layer 2364 including the source electrode wiring, the drain electrode wiring, and the second gate electrode wiring in the second transistor region A2 may be a different layer from the first wiring layer 2361 including the first electrode wiring, the second electrode wiring, and the first gate electrode wiring in the transistor region A1.

A thickness of the second gate electrode 278 of the second transistor 270 may be less than a thickness of an insulation structure 232a included in the first transistor 260. Thus, the additional wiring layer 2364 may be disposed between the second transistor 270 and the first wiring layer 2361, thereby enhancing an integration degree of the wiring layer 236.

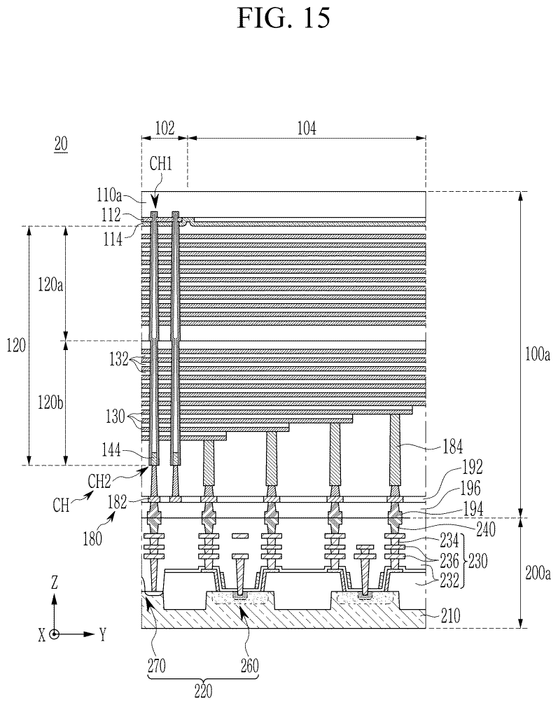

FIG. 15 is a cross-sectional view schematically illustrating a semiconductor device 20 according to an embodiment.

Referring to FIG. 15, a semiconductor device 20 according to an embodiment may have a chip-to-chip (C2C) structure bonded by a wafer bonding type. For example, a lower chip including a circuit region 200a having a first substrate 210 may be manufactured, an upper chip including a cell region 100a having a second substrate 110a may be manufactured, and then a semiconductor device 20 may be manufactured by bonding the lower chip and the upper chip.

The circuit region 200a may include the first substrate 210, a circuit element 220, a first wiring portion 230, and a first bonding structure 240 electrically connected to the first wiring portion 230 at a surface facing the cell region 100a. A region other than the first bonding structure 240 at the surface facing the cell region 100a may be covered by a first insulation layer 232.

The cell region 100a may include a second substrate 110a, a gate stacking structure 120, a channel structure CH, a second wiring portion 180, and a second bonding structure 194 electrically connected the second wiring portion 180 at a surface facing the circuit region 200a. A region other than the second bonding structure 194 may be covered by an insulation layer 196.

In an embodiment, the second substrate 110a may be a semiconductor substrate including a semiconductor material. For example, the second substrate 110a may be a semiconductor substrate of a semiconductor material or may be a semiconductor substrate in which a semiconductor layer is on a base substrate. For example, the second substrate 110a may include single-crystalline or polycrystalline silicon, germanium, silicon-germanium, silicon-on-insulator, germanium-on-insulator, or the like. In some embodiments, the second substrate 110a may be a supporting member including an insulation layer or an insulating material. This is because a semiconductor substrate provided in the cell region 100a may be removed after the cell region 100a is bonded to the circuit region 200a and the supporting member including the insulation layer, or the insulating material may be formed.

In an embodiment, the gate stacking structure 120 may be sequentially stacked on a lower portion of the second substrate 110a in the drawing and may have a structure in which the gate stacking structure 120 is disposed in a vertically inverted manner as illustrated in FIG. 1. The channel structure CH penetrating the gate stacking structure 120 may have a structure in which the channel structure CH is disposed in a vertically inverted manner as illustrated in FIG. 2. Accordingly, in a cross-sectional view, the channel structure CH may have an inclined side surface such that a width of the channel structure CH decreases as the channel structure CH goes from the circuit region 200a towards the second substrate 110a. The channel pad 144 and the second wiring portion 180 at upper portion of the gate stacking structure 120 may be disposed adjacent to the circuit region 200a.

For example, the first bonding structure 240 and/or the second bonding structure 194 may include aluminum, copper, tungsten, or an alloy including the same. For example, the first and second bonding structures 240 and 194 may include copper so that the cell region 100a and the circuit region 200a may be bonded (e.g., directly bonded) to each other by copper-to-copper bonding.

In FIG. 15, it is illustrated as an example that the gate stacking structure 120 includes a plurality of gate stacking structures. However, it is not necessarily limited thereto. In some embodiments, the gate stacking structure 120 may include one gate stacking structure or three or more gate stacking structures. Unless otherwise described, the description of the gate stacking structure 120 and the channel structure CH with reference to FIG. 1 and FIG. 2 may be applied as is. In FIG. 15, it is illustrated as an example that an electrical connection structure between the channel structure CH and the horizontal conductive layers 112 and 114 and/or the second substrate 110 is the same as that of FIG. 2. However, the embodiments are not necessarily limited thereto, and the electrical connection structure between the channel structure CH and the horizontal conductive layers 112 and 114 and/or the second substrate 110 may be modified.

The semiconductor device 20 according to an embodiment may include an input/output pad, and a through plug or an input/output connection wiring electrically connected to the input/output pad. The through plug or the input/output connection wiring may be electrically connected to a part of the second bonding structure 194. For example, the input/output pad may be disposed on an insulation layer covering an outer surface of the second substrate 110a. In some embodiments, an additional input/output pad electrically connected to the circuit region 200a may be provided.

In an embodiment, the circuit region 200a may include a first transistor 260 and a second transistor 270. A first region 264a of the first transistor 260 may be electrically connected to a gate contact portion 184 through a first wiring portion 230, a second bonding structure 240, and a second bonding structure 194. According to an embodiment, the first transistor 260 may be connected to the gate contact portion 184 without a through plug 188 (refer to FIG. 1), thereby simplifying a structure. Unless otherwise described, the description of a structure of the circuit region 200 described with reference to FIG. 1 to FIG. 12 may be applied to the circuit region 200a as is.

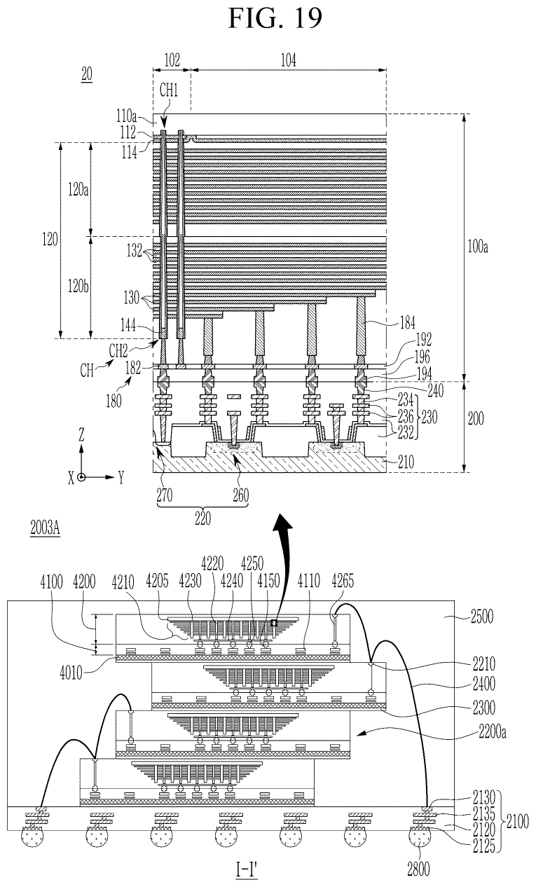

For example, the circuit region 200a and the cell region 100a may be portions corresponding to a first structure 1100F and a second structure 1100S of a semiconductor device 1100 included in an electronic system 1000 illustrated in FIG. 16, respectively. In some embodiments, the circuit region 200a and the cell region 100a may be regions including a first structure 4100 and a second structure 4200 of a semiconductor chip 2200 illustrated in FIG. 19, respectively.

An example of an electronic system including the semiconductor device will be described in detail below.

FIG. 16 is a view schematically illustrating an electronic system including a semiconductor device according to an embodiment.

Referring to FIG. 16, an electronic system 1000 according to an embodiment may include a semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid-state drive (SSD) device, a universal serial bus (USB), a computing system, a medical device, or a communication device including one or a plurality of semiconductor devices 1100.

The semiconductor device 1100 may be a non-volatile memory device such as, for example, a NAND flash memory device described with reference to FIG. 1 to FIG. 15. The semiconductor device 1100 may include a first structure 1100F and a second structure 1100S disposed on the first structure 1100F. In some embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, first and second gate upper lines UL1 and UL2, first and second gate lower lines LL1 and LL2, and a memory cell string CSTR disposed between the bit line BL and the common source line CSL.

In the second structure 1100S, each of memory cell strings CSTR may include lower transistors LT1 and LT2 disposed adjacent to the common source line CSL, upper transistors UT1 and UT2 disposed adjacent to the bit line BL, and a plurality of memory cell transistors MCT disposed between the lower transistors LT1 and LT2 and the upper transistors UT1 and UT2. A number of the lower transistors LT1 and LT2 and a number of the upper transistors UT1 and UT2 may be modified according to an embodiment.

In an embodiment, the lower transistors LT1 and LT2 may include a ground selection transistor, and the upper transistors UT1 and UT2 may include a string selection transistor. The first and second gate lower lines LL1 and LL2 may be gate lines of the lower transistors LT1 and LT2, respectively. The word line WL may be a gate line of the memory cell transistor MCT, and the gate upper lines UL1 and UL2 may be gate lines of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 extending towards the second structure 1100S within the first structure 1100F. The bit line BL may be electrically connected to the page buffer 1120 through a second connection wiring 1125 extending towards the second structure 1100S within the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wiring 1135 extending to the second structure 1100S within the first structure 1100F.

The controller 1200 may include a processor 1210, a NAND controller 1220, and a host interface 1230. According to an embodiment, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or the like may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

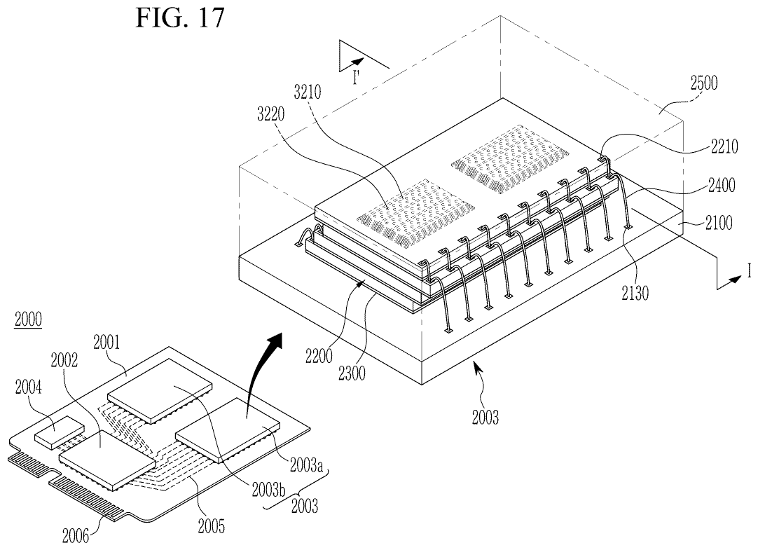

FIG. 17 is a perspective view schematically illustrating an electronic system including a semiconductor device according to an embodiment.

Referring to FIG. 17, an electronic system 2000 according to an embodiment may include a main substrate 2001, a controller 2002 disposed on the main substrate 2001, one or more semiconductor packages 2003, and a Dynamic Random Access Memory (DRAM) 2004. The semiconductor package 2003 and the DRAM 2004 may be connected to the controller 2002 through a wiring pattern 2005 at the main substrate 2001. The main substrate 2001 may include a connector 2006 including a plurality of pins coupled to the external host. A number and an arrangement of the plurality of pins in the connector 2006 may vary depending on a communication interface between the electronic system 2000 and the external host. In an embodiment, the electronic system 2000 may communicate with the external host according to any one of interfaces such as a universal serial bus (USB), a peripheral component interconnect express (PCI-Express), a serial advanced technology attachment (SATA), and an M-Phy for a universal flash storage (UFS). In an embodiment, the electronic system 2000 may operate by power supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003 and may improve an operating speed of the electronic system 2000.

The DRAM 2004 may be a buffer memory for mitigating or buffering a speed difference between the semiconductor package 2003, which is a data storage space, and the external host. The DRAM 2004 included in the electronic system 2000 may also be a kind of cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package 2003 including a plurality of semiconductor chips 2200. Each of the first and second semiconductor packages 2003a and 2003b may include a package substrate 2100, the semiconductor chip 2200 disposed on the package substrate 2100, an adhesive layer 2300 disposed at a lower surface of each semiconductor chip 2200, a connection structure 2400 electrically connecting the semiconductor chip 2200 and the package substrate 2100, and a molding layer 2500 which at least partially covers the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 15. Each semiconductor chip 2200 may include a gate stacking structure 3210 and a channel structure 3220. The semiconductor chip 2200 may include the semiconductor device described with reference to FIG. 1 to FIG. 15.

In an embodiment, the connection structure 2400 may be a bonding wire electrically connecting the input/output pad 2210 and the package upper pad 2130. Accordingly, in each of the first and second semiconductor packages 2003a and 2003b, the semiconductor chips 2200 may be electrically connected to each other using a bonding wire type, and the semiconductor chip 2200 may be electrically connected to a package upper pad 2130 of the package substrate 2100. According to an embodiment, in each of the first and second semiconductor packages 2003a and 2003b, the semiconductor chips 2200 may be electrically connected to each other by a connection structure including a through silicon via (TSV) instead of the connection structure 2400 using the bonding wire type.

In an embodiment, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wiring at the interposer substrate.

FIG. 18 and FIG. 19 are cross-sectional views schematically illustrating semiconductor packages according to embodiments, respectively. FIG. 18 and FIG. 19 respectively describe embodiments of the semiconductor package 2003 of FIG. 17, and conceptually illustrate a region obtained by cutting the semiconductor package 2003 of FIG. 17 along a line I-I′.

Referring to FIG. 18, in the semiconductor package 2003, the package substrate 2100 may be a printed circuit board. The package substrate 2100 may include a package substrate body portion 2120, a package upper pad 2130 disposed at an upper surface of the package substrate body portion 2120, a lower pad 2125 disposed at a lower surface of the package substrate body portion 2120 or exposed through the lower surface of the package substrate body portion 2120, and an internal wiring 2135 electrically connecting the package upper pad 2130 and the package lower pad 2125 inside the package substrate body portion 2120. The package upper pad 2130 may be electrically connected to the connection structure 2400. The package lower pad 2125 may be connected to a wiring pattern 2005 of the main substrate 2001 of the electronic system 2000, as illustrated in FIG. 17, through a conductive connection portion 2800.

The semiconductor chip 2200 may include a semiconductor substrate 3010, and a first structure 3100 and a second structure 3200 sequentially stacked on the semiconductor substrate 3010. The first structure 3100 may include a peripheral circuit region including a peripheral wiring 3110. The second structure 3200 may include a common source line 3205, a gate stacking structure 3210 disposed on the common source line 3205, a channel structure 3220 and a separation structure 3230 penetrating the gate stacking structure 3210, a bit line 3240 electrically connected to the channel structure 3220, and a gate connection wiring electrically connected to a word line WL (refer to FIG. 16) of the gate stacking structure 3210.

In a semiconductor chip 2200 or a semiconductor device according to an embodiment, performance and an integration degree of the semiconductor chip 2200 or the semiconductor device may be enhanced by a first transistor 260 having a vertical structure and including a partial portion of a semiconductor substrate or being adjacent to the semiconductor substrate.

Each of the semiconductor chips 2200 may include a through wiring 3245 that is electrically connected to a peripheral wiring 3110 of the first structure 3100 and extends into the second structure 3200. The through wiring 3245 may penetrate the gate stacking structure 3210 and may be further provided at an outside of the gate stacking structure 3210. Each semiconductor chip 2200 may further include an input/output connection wiring 3265 electrically connected to the peripheral wiring 3110 of the first structure 3100 and extending into the second structure 3200, and an input/output pad 2210 electrically connected to the input/output connection wiring 3265.

In an embodiment, in the semiconductor package 2003, a plurality of semiconductor chips 2200 may be electrically connected to each other by a connection structure 2400 having a bonding wire type. In some embodiments, the plurality of semiconductor chips 2200 or a plurality of portions constituting the plurality of semiconductor chips 2200 may be electrically connected by a connection structure including a through silicon via (TSV).

Referring to FIG. 19, in a semiconductor package 2003A, each semiconductor chip 2200a may include a semiconductor substrate 4010, a first structure 4100 disposed on the semiconductor substrate 4010, and a second structure 4200 disposed on the first structure 4100 and bonded to the first structure 4100 by a wafer bonding type.

The first structure 4100 may include a peripheral circuit region including a peripheral wiring 4110 and a first bonding structure 4150. The second structure 4200 may include a common source line 4205, a gate stacking structure 4210 disposed between the common source line 4205 and the first structure 4100, a channel structure 4220 and a separation structure 4230 penetrating the gate stacking structure 4210, and a second bonding structure 4250 electrically connected to the channel structure 4220 and a word line WL (refer to FIG. 16) of the gate stacking structure 4210. For example, the second bonding structure 4250 may be electrically connected to the channel structure 4220 and the word line WL through a bit line 4240 electrically connected to the channel structure 4220 and a gate connection wiring electrically connected to the word line WL. The first bonding structure 4150 of the first structure 4100 and the second bonding structure 4250 of the second structure 4200 may be in contact with and bonded to each other. For example, portions of the first bonding structure 4150 and the second bonding structure 4250 where the first bonding structure 4150 and the second bonding structure 4250 are bonded may include copper (Cu).

In a semiconductor chip 2200a or a semiconductor device according to an embodiment, performance and an integration degree of the semiconductor chip 2200a or the semiconductor device may be enhanced by a first transistor 260 having a vertical structure and including a partial portion of a semiconductor substrate or being adjacent to the semiconductor substrate.

Each of the semiconductor chips 2200a may further include an input/output pad 2210 and an input/output connection wiring 4265 at a lower portion of the input/output pad 2210. The input/output connection wiring 4265 may be electrically connected to a part of the second bonding structure 4250.

In an embodiment, in the semiconductor package 2003A, a plurality of semiconductor chips 2200a may be electrically connected to each other by the connection structure 2400 having a bonding wire type. In some embodiments, the plurality of semiconductor chips 2200a or a plurality of portions constituting the plurality of semiconductor chips 2200a may be electrically connected by a connection structure including a through silicon via (TSV).

While some examples have been described in connection with what is presently considered to be some practical embodiments, it is to be understood that the disclosure is not necessarily limited to the disclosed embodiments, and that that the disclosure is intended to cover various modifications and equivalent arrangements included within the spirit and scope of the appended claims.

What is claimed is:

1. A semiconductor device, comprising:
a semiconductor substrate; and
a first transistor disposed on the semiconductor substrate,
wherein the first transistor includes:
an insulation structure disposed on the semiconductor substrate;
a channel region disposed on the insulation structure and including a first semiconductor layer,
wherein the channel region extends in a direction crossing the semiconductor substrate;
first source and drain regions electrically connected to the channel region;
a first gate insulating layer disposed on the channel region; and
a first gate electrode disposed on the first gate insulating layer,
wherein a first region that is one of the first source and drain regions and a second region that is another one of the first source and drain regions include different materials or have different crystal structures.

2. The semiconductor device of claim 1, wherein the first region includes a second semiconductor layer having a conductivity type opposite to a conductive type of the channel region, and
wherein the second region includes a partial portion of the semiconductor substrate.

3. The semiconductor device of claim 2, wherein the first semiconductor layer and the second semiconductor layer are connected to each other.

4. The semiconductor device of claim 1, wherein the first region is disposed on the insulation structure,
wherein the second region is disposed on or at one surface of the semiconductor substrate, and
wherein a first side of the channel region is connected to the first region, and a second side of the channel region that is opposite to the first side of the channel region is connected to the one surface of the semiconductor substrate or the second region.

5. The semiconductor device of claim 1, wherein a thickness of the channel region or a thickness of the first region is less than a thickness of the second region.

6. The semiconductor device of claim 1, wherein the channel region includes a portion at least partially surrounded by the insulation structure and the first gate insulating layer.

7. The semiconductor device of claim 1, wherein the channel region or the first gate electrode is inclined or vertical to a first surface or a second surface of the semiconductor substrate.

8. The semiconductor device of claim 1, wherein the first transistor is one of a pair of first transistors adjacent to each other in one direction,
wherein the second region is shared by the pair of first transistors, and
wherein the pair of first transistors has a symmetrical structure in the one direction with respect to the second region.

9. The semiconductor device of claim 1, further comprising:
a first contact connected to the first region and a second contact connected to the second region,
wherein the second region includes a low concentration region and a high concentration region having a doping concentration higher than a doping concentration of the low concentration region, and
wherein the second contact is connected to the high concentration region.

10. The semiconductor device of claim 9, wherein the channel region is connected to the low concentration region.

11. The semiconductor device of claim 1, wherein the channel region is connected to a bulk region of the semiconductor substrate.

12. The semiconductor device of claim 1, further comprising:
a second transistor having an operating voltage less than an operating voltage of the first transistor and having a structure different from a structure of the first transistor.

13. The semiconductor device of claim 12, wherein the second transistor includes a second gate insulating layer disposed on the semiconductor substrate, a second gate electrode disposed on the second gate insulating layer, and second source and drain regions disposed at both sides of the second gate electrode, respectively, and
wherein the second source and drain regions each include a partial portion of the semiconductor substrate.

14. The semiconductor device of claim 13, wherein a thickness of the insulation structure, a length of a side surface of the insulation structure, or a length of the channel region is greater than a thickness of the second gate electrode included in the second transistor.

15. The semiconductor device of claim 13, wherein a thickness of the insulation structure, a length of a side surface of the insulation structure, or a length of the channel region is greater than a distance between the second source region and the second drain region in the second transistor.

16. The semiconductor device of claim 1, wherein a gate contact connected to the first gate electrode is disposed at a first position in one direction, and
a first contact connected to the first region and a second contact connected to the second region are disposed at a second position different from the first position in the one direction.

17. The semiconductor device of claim 1, further comprising:
a circuit region including the semiconductor substrate and the first transistor; and
a cell region disposed on the circuit region and including a memory cell structure.

18. A semiconductor device, comprising:
a semiconductor substrate; and
a plurality of transistors disposed on the semiconductor substrate and including a first transistor and a second transistor having different structures;
wherein the first transistor includes:
an insulation structure disposed on the semiconductor substrate;
a channel region disposed on the insulation structure and including a first semiconductor layer,
wherein the channel region extends in a direction inclined or vertical to the semiconductor substrate;
source and drain regions electrically connected to the channel region;
a gate insulating layer disposed on the channel region; and
a gate electrode disposed on the gate insulating layer,
wherein one of the source and drain regions includes a partial portion of the semiconductor substrate.

19. The semiconductor device of claim 18, wherein the first transistor has a vertical channel structure, and the second transistor has a planar channel structure.

20. An electronic system, comprising:
a main substrate;
a semiconductor device disposed on the main substrate; and
a controller electrically connected to the semiconductor device on the main substrate,
wherein the semiconductor device comprises a semiconductor substrate, and a first transistor disposed on the semiconductor substrate,
wherein the first transistor includes:
an insulation structure disposed on the semiconductor substrate;
a channel region disposed on the insulation structure and including a first semiconductor layer,
wherein the channel region extends in a direction crossing the semiconductor substrate;
source and drain regions electrically connected to the channel region;
a gate insulating layer disposed on the channel region; and
a gate electrode disposed on the gate insulating layer,
wherein a first region that is one of the source and drain regions and a second region that is another one of the source and drain regions include different materials or have different crystal structures.
